(19) United States
(12) Patent Application Publication
(10) Pub. No.: US 2025/0014991 A1
(43) Pub. Date: Jan. 9, 2025

(54) SEMICONDUCTOR DEVICE

(71) Applicant: United Microelectronics Corp., Hsinchu (TW)

(72) Inventor: Chia-Chen Sun, Kaohsiung City (TW)

(73) Assignee: United Microelectronics Corp., Hsinchu (TW)

(21) Appl. No.: 18/446,430

(22) Filed: Aug. 8, 2023

(30) Foreign Application Priority Data
Jul. 5, 2023 (TW) 112125089

(51) Int. Cl. H01L 23/522; H01L 23/528; H01L 27/06

(52) U.S. Cl. CPC H01L 23/5228; H01L 23/528; H01L 27/0629; H01L 28/24

(57) ABSTRACT

Provided is a semiconductor device including a conductive layer, a stop layer, a second dielectric layer disposed on a first dielectric layer and a resistor. The resistor includes a part of the conductive layer, a first strip-like contact, a second strip-like contact, a first auxiliary contact, a second auxiliary contact, a third auxiliary contact and a fourth auxiliary contact. The first strip-like contact and the second strip-like contact respectively extend through the second dielectric layer and the stop layer, and are electrically connected to the conductive layer. The first auxiliary contact and the second auxiliary contact sandwich the first strip-like contact therebetween, extend through the second dielectric layer, and are electrically connected to the conductive layer. The third auxiliary contact and the fourth auxiliary contact sandwich the second strip-like contact therebetween, extend through the second dielectric layer and are electrically connected to the conductive layer.

### CROSS-REFERENCE TO RELATED APPLICATION

This application claims the priority benefit of Taiwan application serial no. 112125089, filed on Jul. 5, 2023. The entirety of the above-mentioned patent application is hereby incorporated by reference herein and made a part of the specification.

### BACKGROUND

### Technical Field

The present disclosure is related to an integrated circuit, and particularly to a semiconductor device.

### Description of Related Art

A resistor is a common device in an electronic circuit. A resistor can be integrated into an integrated circuit. When a resistor is used in an electronic circuit, it is necessary to consider whether the allowable resistance error of the resistor is compatible with the application. For some precise circuits, the allowable resistance error of the resistor is small, so controlling the resistance value of the resistor is a very important topic.

### SUMMARY

The present disclosure provides a semiconductor device that can reduce the contact sheet resistance between contacts and a resistance layer, and reduce the impact of contact variation on the total resistance of the resistor.

According to some embodiments of the present disclosure, a semiconductor device includes a first dielectric layer, a conductive layer, a stop layer, a second dielectric layer, a first strip-like contact, a second strip-like contact, a first auxiliary contact, a second auxiliary contact, a third auxiliary contact and a fourth auxiliary contact. The conductive layer is disposed on the first dielectric layer. The stop layer is disposed on the conductive layer. The second dielectric layer is disposed on the conductive layer. The first strip-like contact and the second strip-like contact are separated from each other by a non-zero distance, extend through the second dielectric layer and the stop layer, and are electrically connected to the conductive layer. The first auxiliary contact and the second auxiliary contact sandwich the first strip-like contact therebetween, extend through the second dielectric layer, and are electrically connected to the conductive layer. The third auxiliary contact and the fourth auxiliary contact sandwich the second strip-like contact therebetween, extend through the second dielectric layer, and are electrically connected to the conductive layer. The first strip-like contact, the second strip-like contact, the conductive layer between the first strip-like contact and the second strip-like contact, the first auxiliary contact, the second auxiliary contact, the third auxiliary contact and the fourth auxiliary contact together constitute a resistor.

In an embodiment of present disclosure, a semiconductor device includes a first dielectric layer, a resistance layer, a stop layer, a second dielectric layer, a first group of grid-like contacts and a second group of grid-like contacts. The resistance layer is disposed on the first dielectric layer. The stop layer is disposed on the resistance layer. The second dielectric layer is disposed on the stop layer. The first group of grid-like contacts and the second group of grid-like contacts are separated by a non-zero distance, extend through the second dielectric layer and the stop layer, and are electrically connected to the resistance layer. The first group of grid-like contacts, the second group of grid-like contacts and the resistance layer between the first group of grid-like contacts and the second group of grid-like contacts together constitute a resistor.

Based on the above, the present disclosure provides a semiconductor device, in which contacts of a resistor have a strip-like shape, so as to reduce the contact sheet resistance between the contacts and the resistance layer. The shapes and dimensions of the strip-like contacts can be controlled by disposing auxiliary contacts at two sides of the strip-like contacts. The disposition of the auxiliary contacts can further reduce the contact sheet resistance between the contacts and resistance layer, and therefore reduce the impact of contact variation on the total resistance of the resistor.

### BRIEF DESCRIPTION OF THE DRAWINGS

FIG. 1 is a schematic diagram of a circuit of a resistor in FIG. 2 or FIG. 5.

FIG. 2 is a top view of a semiconductor device according to an embodiment of the present disclosure.

FIG. 3A and FIG. 4A are schematic cross-sectional views taken along the line III-III′ and the line IV-IV′ in FIG. 2 according to some embodiments.

FIG. 3B and FIG. 4B are schematic cross-sectional views taken along the line III-III′ and the line IV-IV′ in FIG. 2 according to other embodiments.

FIG. 5 is a top view of a semiconductor device according to another embodiment of the present disclosure.

FIG. 6A and FIG. 7A are schematic cross-sectional views taken along the line VI-VI′ and the line VII-VII′ in FIG. 5 according to some embodiments.

FIG. 6B and FIG. 7B are schematic cross-sectional views taken along the line VI-VI′ and the line VII-VII′ in FIG. 5 according to other embodiments.

FIG. 8A to FIG. 8F are top views of various groups of contacts according to some embodiments of the present disclosure.

### DESCRIPTION OF THE EMBODIMENTS

In the embodiment of the present disclosure, the contacts connecting to the resistance layer (e.g., conductive layer) are designed to have a strip-like shape, and such contacts are referred to as “strip-like contacts” hereinafter. Besides, auxiliary contacts are disposed at two sides of the strip-like contacts. Designing such stripe-like contacts can reduce the contact sheet resistance between the contacts and the resistance layer (e.g., conductive layer). Disposing the auxiliary contacts at two sides of the strip-like contacts can control the shapes and dimensions of the strip-like contacts, improve the uniformity, reduce the contact sheet resistance between the contacts and the resistance layer (e.g., conductive layer), and therefore reduce the impact of contact variation on the total resistance of the resistor.

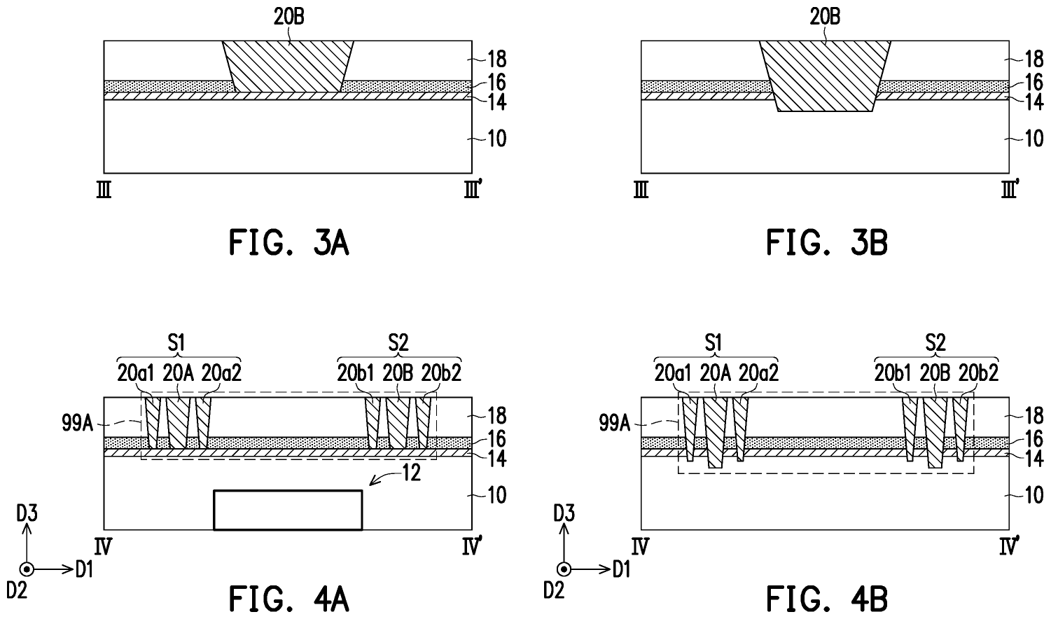

FIG. 2 is a top view of a semiconductor device according to an embodiment of the present disclosure FIG. 3A and FIG. 4A are schematic cross-sectional views taken along the line III-III′ and the line IV-IV′ in FIG. 2 according to some embodiments. FIG. 3B and FIG. 4B are schematic cross-sectional views taken along the line III-III′ and the line IV-IV′ in FIG. 2 according to other embodiments.

Referring to FIG. 2, FIG. 3A and FIG. 4A, a semiconductor device 100A of an embodiment of the present disclosure includes a first dielectric layer 10, a conductive layer (e.g., resistance layer) 14, a stop layer 16, a second dielectric layer 18, a first group of contacts S1, and a second group of contacts S2.

Referring to FIG. 3A and FIG. 4A, the first dielectric layer 10 may be any dielectric layer disposed on a substrate (not shown), such as an inter-layer dielectric layer or an inter-metal dielectric layer. The substrate may be a semiconductor substrate, such as silicon substrate or a silicon germanium substrate. The substrate may be a silicon-on-insulator (SOI) substrate. The substrate may be a planar substrate, or a substrate with a fin-like structure.

The first dielectric layer 10 may have a single-layer or multi-layer structure. The first dielectric layer 10 includes silicon oxide, phosphosilicate glass, borophosphosilicate glass, a low-k material, an ultra-low-k material or a combination thereof. The first dielectric layer 10 may be planarized through a planarization process (e.g., a chemical mechanical polishing process or an etch-back process), so as to have a flat surface.

Referring to FIG. 3A and FIG. 4A, the stop layer 16 is disposed on the first dielectric layer 10. The second dielectric layer 18 is disposed on the stop layer 16. The material of the stop layer 16 is different from the material of the first dielectric layer 10 and the second dielectric layer 18. The stop layer 16 includes a nitride dielectric material, such as silicon nitride, silicon oxynitride or a combination thereof. The second dielectric layer 18 may have a single-layer or multi-layer structure. The second dielectric layer 18 includes silicon oxide, phosphosilicate glass, borophosphosilicate glass, a low-k material, an ultra-low-k material or a combination thereof. The second dielectric layer 18 may be planarized through a planarization process (e.g., a chemical mechanical polishing process or an etch-back process), so as to have a flat surface.

Referring to FIG. 3A and FIG. 4A, the conductive layer 14 is disposed between the first dielectric layer 10 and the stop layer 16. In this embodiment, the conductive layer 14 may serve as a resistance layer. The sheet resistance of the conductive layer 14 as a resistance layer may be, for example, from about 350 ohm/sq to about 850 ohm/sq. The conductive layer 14 may include a metal, an alloy, a metal nitride material or a combination thereof. The conductive layer 14 includes TiN, SiCr (silicon-chromium), SiCCr (silicon-silicon carbide-chromium), TaN (tantalum nitride), NiCr (nickel-chromium), AlNiCr (aluminum-doped nickel-chromium), TiNiCr (titanium-nickel-chromium), or a combination thereof. The conductive layer 14 may have a single-layer or multi-layer structure.

Referring to FIG. 2, the conductive layer 14 is a patterned conductive layer. The conductive layer 14 may have a rectangular shape or a strip-like shape, for example. The length 14L (having a length dimension LR) of the conductive layer 14 extends along a direction D1, and the width 14 W (having a width dimension WR) of the conductive layer 14 extends along a direction D2. The semiconductor device 100A may further include multiple dummy conductive layers (or called “dummy resistance layers”) 14a and 14b. The multiple dummy conductive layers 14a and 14b are disposed at two sides of the conductive layer 14, respectively. The multiple dummy conductive layers 14a and 14b can have the same material as the conductive layer 14, may be formed in the same deposition process, and may be patterned in the same patterning process. During the patterning process, the disposition of the multiple dummy conductive layers 14a and 14b can reduce or avoid the influence of the optical proximity effect, make the conductive layer 14 have a more controllable shape and dimension, and improve the overall uniformity of the wafer. The multiple dummy conductive layers 14a and 14b may have a rectangular shape, a strip-like shape or any other possible shape.

Referring to FIG. 2, FIG. 3A and FIG. 4A, the first group of contacts S1 and the second group of contacts S2 are electrically connected to the conductive layer 14. In an embodiment of present disclosure, the first group of contacts S1 includes a first strip-like contact 20A, a first auxiliary contact 20al and a second auxiliary contact 20a2. The first strip-like contact 20A is sandwiched between the first auxiliary contact 20al and the second auxiliary contact 20a2. The second group of contacts S2 includes a second strip-like contact 20B, a third auxiliary contact 20b1 and a fourth auxiliary contact 20b2. The second strip-like contact 20B is sandwiched between the third auxiliary contact 20b1 and the fourth auxiliary contact 20b2. The first strip-like contact 20A and the second strip-like contact 20B is separated from each other by a non-zero distance.

Referring to FIG. 3A and FIG. 4A, in some embodiments, the first group of contacts S1 and the second group of contacts S2 may be landed on the conductive layer 14. More specifically, the first strip-like contact 20A, the first auxiliary contact 20al and the second auxiliary contact 20a2 of the first group of contacts S1 extend in a direction D3, penetrate through the second dielectric layer 18 and the stop layer 16, and are landed on the conductive layer 14, and their the bottom surfaces are electrically connected to the conductive layer 14. The second strip-like contact 20B, the third auxiliary contact 20b1 and the fourth auxiliary contact 20b2 of the second group of contacts S2 extend in the direction D3, penetrate through the second dielectric layer 18 and the stop layer 16, and are landed on the conductive layer 14, and their bottom surfaces are in contact with and electrically connected to the conductive layer 14.

Referring to FIG. 3B and FIG. 4B, in some other embodiments, the first group of contacts S1 and the second group of contacts S2 extend in the direction D3, penetrate through the bottom surface of the conductive layer 14, and extend into the first dielectric layer 10. In some embodiments, the dimensions of first strip-like contact 20A and second strip-like contact 20B are greater than the dimensions of the first auxiliary contact 20a1, the second auxiliary contact 20a2, the third auxiliary contact 20b1 and the fourth auxiliary contact 20b2, and the depths of first strip-like contact 20A and second strip-like contact 20B are deeper than the depths of the first auxiliary contact 20a1, the second auxiliary contact 20a2, the third auxiliary contact 20b1 and the fourth auxiliary contact 20b2. The sidewalls of the first strip-like contact 20A, the second strip-like contact 20B, the first auxiliary contact 20a1, the second auxiliary contact 20a2, and the third auxiliary contact 20b1 are in contact with and are electrically connected to the conductive layer 14.

Referring to FIG. 2, FIG. 4A and FIG. 4B, in an embodiment of the present disclosure, the first group of contacts S1, the second group of contacts S2, and the conductive layer 14 disposed between the first group of contacts S1 and the second group of contacts S2 together form a resistor 99A. That is to say, the first strip-like contact 20A, the second strip-like contact 20B, the conductive layer 14 between the first strip-like contact 20A and the second strip-like contact 20B, the first auxiliary contact 20a1, the second auxiliary contact 20a2, the third auxiliary contact 20b1 and the fourth auxiliary contact 20b2 together constitute the resistor 99A.

In the embodiment as shown in FIG. 4A, the first group of contacts S1 and the second group of contacts S2 are landed on the conductive layer 14. Since the first group of contacts S1 and the second group of contacts S2 do not extend into the first dielectric layer 10, a device 12 may be disposed in the first dielectric layer 10 right below the conductive layer 14. In other words, the device 12 may be disposed right below the resistor 99A to effectively utilize the chip area. The device 12 may be an active device or a passive device. The active device may be a transistor, such as a metal oxide semiconductor (MOS) transistor, such as an NMOS transistor, a PMOS transistor, or a CMOS device. The passive device may be, for example, a capacitor, an inductor or a combination thereof.

In the embodiment as shown in FIG. 4B, since the first group of contacts S1 and the second group of contacts S2 extend into the first dielectric layer 10, the device 12 as shown in FIG. 4A is not disposed in the first dielectric layer 10 below the conductive layer 14. In other words, the device 12 is not disposed right below the resistor 99A, so as to avoid a short circuit between the device 12 and the first group of contacts S1 or the second group of contacts S2 of the resistor 99A.

In the embodiment as shown in FIG. 2, the shape of each of the first auxiliary contact 20a1, the second auxiliary contact 20a2, the third auxiliary contact 20b1 and the fourth auxiliary contact 20b2 may have a strip-like shape, for example. In some embodiments, the first group of contacts S1 including the first strip-like contact 20A, the first auxiliary contact 20a1, and the second auxiliary contact 20a2 may be called a “first group of grid-like contacts”. The second group of contacts S2 including the second strip-like contact 20B, the third auxiliary contact 20b1 and the fourth auxiliary contact 20b2 may be called a “second group of grid-like contacts”. However, the shapes of the first auxiliary contact 20a1, the second auxiliary contact 20a2, the third auxiliary contact 20b1 and the fourth auxiliary contact 20b2 may have various shapes, which are not limited to those shapes as shown in FIG. 2.

The dimension of the first auxiliary contact 20al or the second auxiliary contact 20a2 may be the same as or smaller than the dimension of the first strip-like contact 20A. The dimension of the third auxiliary contact 20b1 or the fourth auxiliary contact 20b2 may be the same as or smaller than the dimension of the second strip-like contact 20B.

Referring to FIG. 2, in some embodiments, according to the design rules, the width dimension Wa1 of the first auxiliary contact 20al and the width dimension Wa2 of the second auxiliary contact 20a2 are respectively 95%-100% of the width dimension WA of the first strip-like contact 20A. The width dimension Wb1 of the third auxiliary contact 20b1 and the width dimension Wb2 of the fourth auxiliary contact 20b2 are respectively 95%-100% of the width dimension WB of the second strip-like contact 20B. The length dimension La1 of the first auxiliary contact 20al and the length dimension La2 of the second auxiliary contact 20a2 may be the same as or different from the length dimension LA of the first strip-like contact 20A. The length dimension Lb1 of the third auxiliary contact 20b1 and the length dimension Lb2 of the fourth auxiliary contact 20b2 may be the same as or different from the length dimension LB of the second strip-like contact 20B.

In the embodiment as shown in FIG. 2, the length 14L of the conductive layer 14 extends along the direction D1. The length 20L of the first group of contacts S1 and the second group of contacts S2 extends along the D2 direction. That is to say, the length extension direction D2 (or called “longitudinal extension direction”) of the first group of contacts S1 and the second group of contacts S2 is different from the length extension direction D1 of the conductive layer 14. However, the embodiment of the present disclosure is not limited thereto.

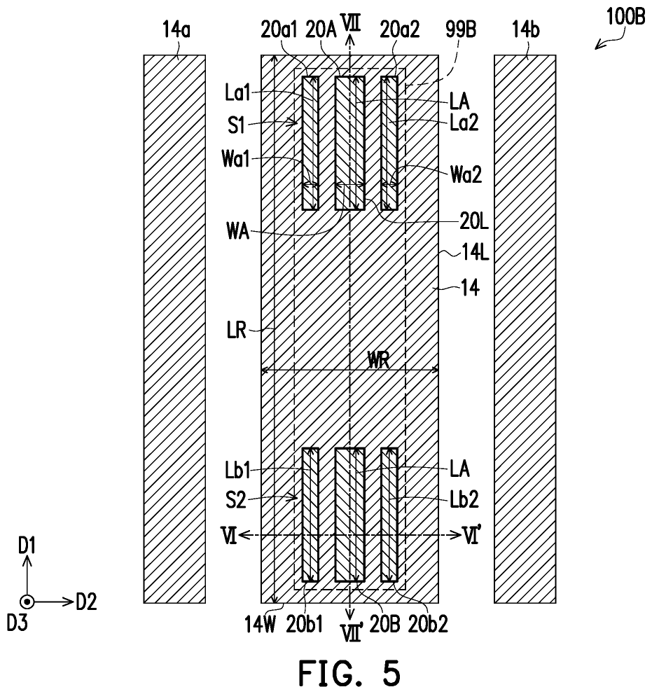

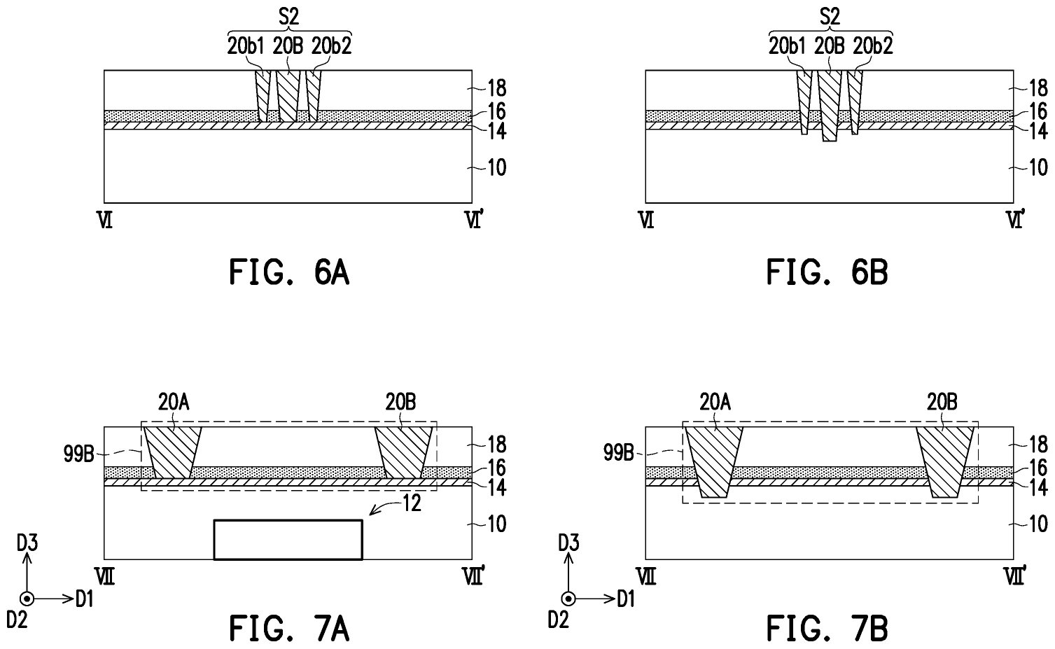

FIG. 5 is a top view of a semiconductor device according to another embodiment of the present disclosure. FIG. 6A and FIG. 7A are schematic cross-sectional views taken along the line VI-VI′ and the line VII-VII′ in FIG. 5 according to some embodiments. FIG. 6B and FIG. 7B are schematic cross-sectional views taken along the line VI-VI′ and the line VII-VII′ in FIG. 5 according to other embodiments.

In the embodiment as shown in FIG. 5, the length 14L (having a length dimension LR) of the conductive layer 14 of the semiconductor device 100B extends along the direction D1. The length 20L of the first group of contacts S1 and the second group of contacts S2 also extends along the direction D1. That is to say, the length extension direction D1 of the first group of contacts S1 and the second group of contacts S2 is the same as the length extension direction D1 of the conductive layer 14.

Similarly, with reference to FIG. 5, FIG. 6A and FIG. 7A, in some embodiments, the first group of contacts S1 and the second group of contacts S2 may be landed on the conductive layer 14. More specifically, the first strip-like contact 20A, the first auxiliary contact 20al and the second auxiliary contact 20a2 extend in the direction D3, penetrate through the second dielectric layer 18 and the stop layer 16, and are landed on the conductive layer 14, and their bottom surfaces are in contact with and electrically connected to the conductive layer 14. The second strip-like contact 20B, the third auxiliary contact 20b1 and the fourth auxiliary contact 20b2 extend in the direction D3, penetrate through the second dielectric layer 18 and the stop layer 16, and are landed on the conductive layer 14, and their bottom surfaces are in contact with and electrically connected to the conductive layer 14.

Referring to FIG. 5, FIG. 6B and FIG. 7B, in some other embodiments, the first group of contacts S1 and the second group of contacts S2 extend in the direction D3, penetrate through the bottom surface of the conductive layer 14, and extend into the first dielectric layer 10. In some embodiments, the dimensions of first strip-like contact 20A and second strip-like contact 20B are greater than the dimensions of the first auxiliary contact 20a1, the second auxiliary contact 20a2, the third auxiliary contact 20b1 and the fourth auxiliary contact 20b2, and the depths of the first strip-like contact 20A and the second strip-like contact 20B are deeper than the depths of the first auxiliary contact 20a1, the second auxiliary contact 20a2, the third auxiliary contact 20b1 and the fourth auxiliary contact 20b2. The sidewalls of the first strip-like contact 20A, the second strip-like contact 20B, the first auxiliary contact 20a1, the second auxiliary contact 20a2, and the third auxiliary contact 20b1 are in contact with and electrically connected to the conductive layer 14.

Referring to FIG. 5, FIG. 6A, FIG. 7A, FIG. 6B and FIG. 7B, in the embodiment of the present disclosure, the first group of contacts S1, the second group of contacts S2, and the conductive layer 14 disposed between the first group of contacts S1 and the second group of contacts S2 together form a resistor 99B. That is to say, the first strip-like contact 20A, the second strip-like contact 20B, the conductive layer 14 between the first strip-like contact 20A and the second strip-like contact 20B, the first auxiliary contact 20a1, the second auxiliary contact 20a2, the third auxiliary contact 20b1 and the fourth auxiliary contact 20b2 together constitute the resistor 99B.

Similarly, in the embodiment as shown in FIG. 7A, the first group of contacts S1 and the second group of contacts S2 are landed on the conductive layer 14. Since the first group of contacts S1 and the second group of contacts S2 do not extend into the first dielectric layer 10, a device 12 may be disposed in the first dielectric layer 10 right below the conductive layer 14. In other words, the device 12 may be disposed right below the resistor 99B to effectively utilize the chip area. The device 12 may be an active device or a passive device. The active device may be a transistor, such as a metal oxide semiconductor (MOS) transistor, such as an NMOS transistor, a PMOS transistor, or a CMOS device. The passive device may be, for example, a capacitor, an inductor or a combination thereof.

In the embodiment as shown in FIG. 7B, since the first group of contacts S1 and the second group of contacts S2 extend into the first dielectric layer 10, the device 12 as shown in FIG. 7A is not disposed in the first dielectric layer 10 below the conductive layer 14. In other words, the device 12 is not disposed right below the resistor 99B to avoid a short circuit between the device 12 and the first group of contacts S1 or the second group of contacts S2 of the resistor 99B.

Referring to FIG. 2 and FIG. 5, in the above embodiment, one end of each of the first strip-like contact 20A, the first auxiliary contact 20al and the second auxiliary contact 20a2 of first group of contacts S1 is connected to conductive layer 14, while another end of each of the first strip-like contact 20A, the first auxiliary contact 20al and the second auxiliary contact 20a2 of the first group of contacts S1 is connected to the same the first terminal. One end of each of the second strip-like contact 20B, the third auxiliary contact 20b1 and the fourth auxiliary contact 20b2 of the second group of contacts S2 is connected to conductive layer 14, while another end of each of the second strip-like contact 20B, the third auxiliary contact 20b1 and the fourth auxiliary contact 20b2 is connected to the same second terminal. The first terminal may be, for example, a first conductive feature disposed over and electrically connected to the top surfaces of the first strip-like contact 20A, the first auxiliary contact 20al and the second auxiliary contact 20a2 of the first group of contacts S1. The second terminal may be, for example, a second conductive feature disposed below and electrically connected to the top surfaces of the second strip-like contact 20B, the third auxiliary contact 20b1 and the fourth auxiliary contact 20b2 of the second group of contacts S2. The first conductive feature and the second conductive feature are separated and electrically insulated from each other.

In an embodiment of the present disclosure, the first auxiliary contact 20al and the second auxiliary contact 20a2 are disposed at two sides of the first strip-like contact 20A, and the third auxiliary contact 20b1 and the fourth auxiliary contact 20b2 are disposed at two sides of the second strip-like contact 20B. The disposition of the first auxiliary contact 20a1, the second auxiliary contact 20a2, the third auxiliary contact 20b1 and the fourth auxiliary contact 20b2 can reduce or avoid the influence of the optical proximity effect of the first strip-like contact 20A and the second strip-like contact 20B, make the first strip-like contact 20A and the second strip-like contact 20B have more controllable shapes and dimensions, and improve the overall uniformity of the wafer.

In addition, as compared to the case in which only first strip-like contact 20A and second strip-like contact 20B are provided without a first auxiliary contact 20a1, a second auxiliary contact 20a2, a third auxiliary contact 20b1 and a fourth auxiliary contact 20b2, an embodiment of the present disclosure is beneficial to reduce the contact sheet resistance between contacts and the conductive layer 14 by disposing the first auxiliary contact 20al and the second auxiliary contact 20a2 at two sides of first strip-like contact 20A and disposing the third auxiliary contact 20b1 and the fourth auxiliary contact act 20b2 at two sides of second strip-like contact 20B. Specifically, the resistance of the first strip-like contact 20A is connected in parallel with the resistances of the adjacent first and second auxiliary contacts 20a1 and 20a2, and the resistance of the second strip-like contact 20B is connected in parallel with the resistances of the adjacent third and fourth auxiliary contacts 20b1 and 20b2. The details are as follows.

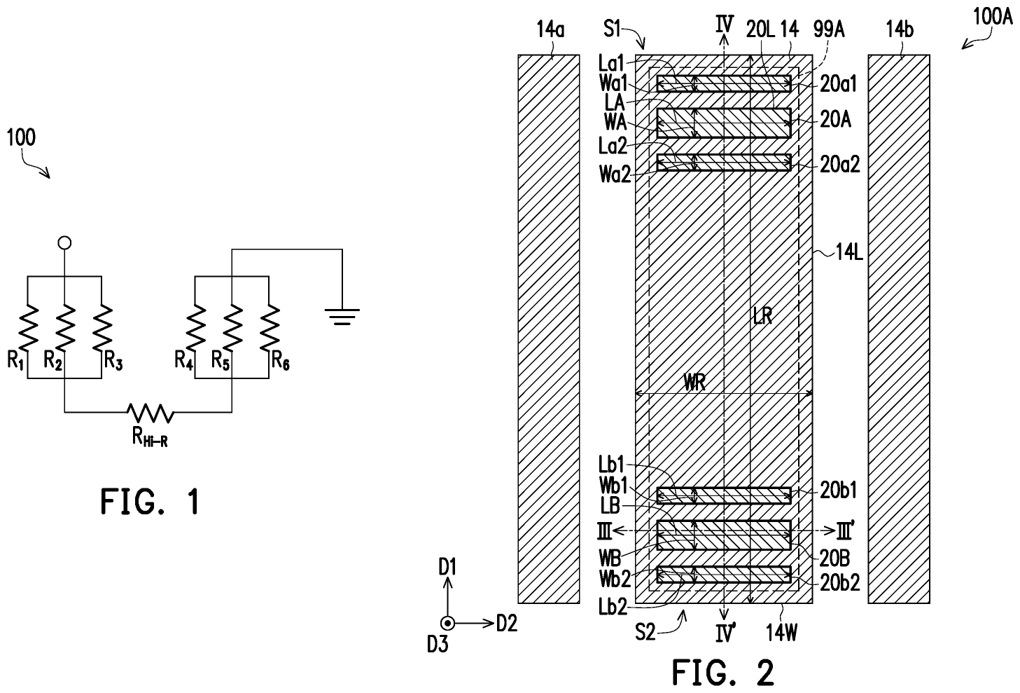

FIG. 1 is a schematic diagram of a circuit 100 of a resistor 99A in FIG. 2 or a resist or 99B in FIG. 5.

Referring to FIG. 1, FIG. 2 and FIG. 5, in the resistor 99A or 99B, the resistance of the conductive layer 14 disposed between the first group of contacts S1 and the second group of contacts S2 is R_{Hi-R}. The first group of contacts S1 has a resistance R_{S1} and the second group of contacts S2 has a resistance R_{S2}. The total resistance R_{Tol} of the resistor 99A or 99B is the sum of the resistances of R_{Hi-R}, R_{S1} and R_{S2} (R_{Tol}=R_{Hi-R}+R_{S1}+R_{S2}).

The resistances of the first auxiliary contact 20a1, the first strip-like contact 20A, and the second auxiliary contact 20a2 are R₁, R₂, and R₃, respectively. Since the first auxiliary contact 20a1, the first strip-like contact 20A, and the second auxiliary contact 20a2 are connected in parallel, the resistance R_{S1} of the first group of contacts S1 is represented by the formula: R_{S1}=1/(1/R₁+1/R₂+1/R₃). The resistances of the third auxiliary contact 20b1, the second strip-like contact 20B and the fourth auxiliary contact 20b2 are R₄, R₅ and R₆, respectively. Since the third auxiliary contact 20b1, the second strip-like contact 20B and the fourth auxiliary contact 20b2 are connected in parallel, the resistance R_{S2} of the second group of contacts S2 is represented by the formula: R_{S2}=1/(1/R₄+1/R₅+1/R₆).

After calculation, the obtained resistance R_{S1} of the first group of contacts S1 is smaller than the resistance R₂ of the first strip-like contact 20A, and the resistance R_{S2} of the second group of contacts S2 is smaller than the resistance R₅ of the second strip-like contact 20B. Therefore, the disposition of the first auxiliary contact 20a1, the second auxiliary contact 20a2, the third auxiliary contact 20b1 and the fourth auxiliary contact 20b2 can reduce the contact sheet resistances of the contacts, and reduce the impact of the contact variation on the total resistance R_{Tol} of the resistor 99A or 99B.

In the embodiment of the present disclosure, the first auxiliary contact 20a1, the second auxiliary contact 20a2, the third auxiliary contact 20b1 and the fourth auxiliary contact 20b2 can make the first strip-like contact 20A and the second strip-like contact 20B have more controllable shapes and dimensions, and therefore improve the overall uniformity of the wafer. The shapes, dimensions, and arrangements of the first auxiliary contact 20a1, the second auxiliary contact 20a2, the third auxiliary contact 20b1 and the fourth auxiliary contact 20b2 may be varied, and are not limited by the embodiments as shown in FIG. 2 and FIG. 5.

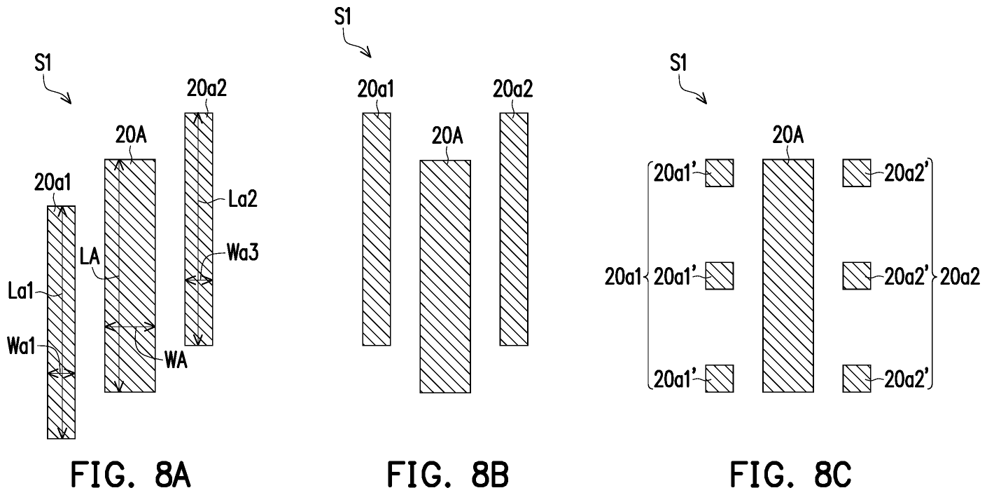

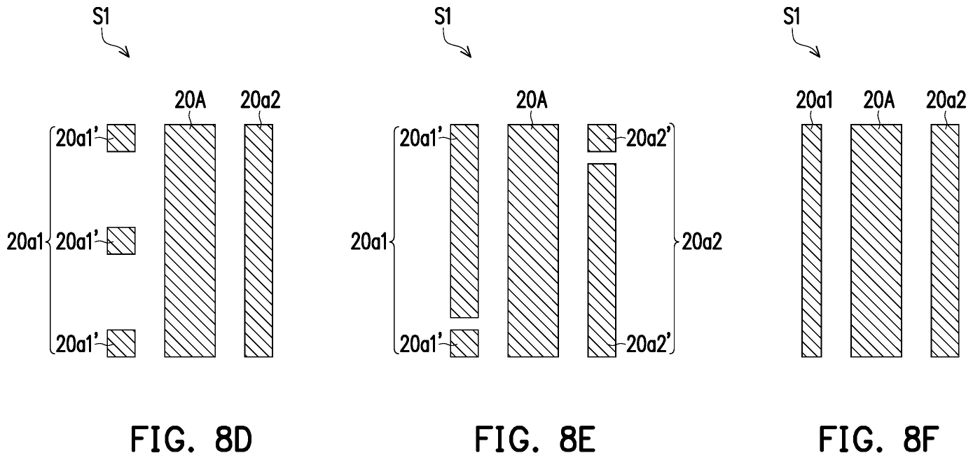

Referring to FIG. 2 and FIG. 5, in the above-mentioned embodiments, in addition to the strip-like shape, the shape of each of the first auxiliary contact 20a1, the second auxiliary contact 20a2, the third auxiliary contact 20b1 and the fourth auxiliary contact 20b2 may have a square shape, a round shape (not shown) or a combination thereof, as shown in FIG. 8A to FIG. 8F.

FIG. 8A to FIG. 8F are top views of various groups of contacts according to some embodiments of the present disclosure. For the sake of brevity, the first auxiliary contact 20al, the second auxiliary contact 20a2 and the first strip-like contact 20A of the first group of contacts S1 are described below. The third auxiliary contact 20b1, the fourth auxiliary contact 20b2 and the second strip-like contact 20B of the second group of contacts S2 may be similar to or the same as the first auxiliary contact 20a1, the second auxiliary contact 20a2 and the first strip-like contact 20A of the first group of contacts S1, so details are not iterated herein.

The first auxiliary contact 20a1 or the second auxiliary contact 20a2 may have the same or similar shape as the shape of the first strip-like contact 20A, as shown in FIG. 8A, FIG. 8B and FIG. 8F. The first auxiliary contact 20al or the second auxiliary contact 20a2 may have different or dissimilar shapes from the shape of the first strip-like contact 20A, as shown in FIG. 8C, FIG. 8D and FIG. 8E.

In some embodiments, the first auxiliary contact 20al or the second auxiliary contact 20a2 may include a single contact, as shown in FIG. 8A, FIG. 8B, FIG. 8D and FIG. 8F. In another embodiment, the first auxiliary contact 20al or the second auxiliary contact 20a2 may include a group of sub-contacts 20al′, 20a2′, as shown in FIG. 8C, FIG. 8D and FIG. 8E. The same group of sub-contacts may have the same shape. For example, the sub-contacts 20al′, 20a2′ of the first auxiliary contact 20al and the second auxiliary contact 20a2 in FIG. 8C as well as the same group of sub-contacts 20al′ of the first auxiliary contact 20al in FIG. 8D are all square sub-contacts. The shape of sub-contacts in the same group may be different. For example, the same group of sub-contacts 20al′ or 20a2′ of the first auxiliary contact 20al or the second auxiliary contact 20a2 in FIG. 8E include square and strip-like sub-contacts.

Furthermore, the shape of the first auxiliary contact 20al may be the same as, similar to or different from the shape of the second auxiliary contact 20a2. For example, with reference to FIG. 8A and FIG. 8C, the shape of the first auxiliary contact 20al is the same as the shape of the second auxiliary contact 20a2, such as strip-like contacts in FIG. 8A and square contacts in FIG. 8C, respectively. For example, with reference to FIG. 8E, the sub-contacts 20al′ of the first auxiliary contact 20al and the sub-contacts 20a2′ of the second auxiliary contact 20a2 have the same shape, each of which contains square and strip-like sub-contacts. For example, with reference to FIG. 8F, the first auxiliary contact 20al is similar in shape to the second auxiliary contact 20a2. For example, with reference to FIG. 8D, the shape of the sub-contacts 20al′ of the first auxiliary contact 20al is different from the shape of the second auxiliary contact 20a2.

The width dimension Wa1 of the first auxiliary contact 20al or the dimension (such as length dimension or width dimension) of the second auxiliary contact 20a2 may be equal to or different from the dimension (such as length dimension or width dimension) of the first strip-like contact 20A.

In FIG. 8A to FIG. 8F, the width dimension Wa1 of the first auxiliary contact 20al or the width dimension Wa2 of the second auxiliary contact 20a2 may be equal to or smaller than the width dimension WA of the first strip-like contact 20A (for brevity, only shown in FIG. 8A). In some embodiments, according to the design rules, the width dimension Wa1 of the first auxiliary contact 20al and the width dimension Wa2 of the second auxiliary contact 20a2 are respectively 95%-100% of the width dimension WA of the first strip-like contact 20A.

In FIG. 8A to FIG. 8F, the length dimension La1 of the first auxiliary contact 20a1 or the length dimension La2 of the second auxiliary contact 20a2 may be the same as or different from the length dimension LA of the first strip-like contact 20A (for brevity, only marked in FIG. 8A).

In FIG. 8A to FIG. 8F, the first auxiliary contact 20a1, the first strip-like contact 20A and the second auxiliary contact 20a2 may be arranged in various arrangements. For example, the first auxiliary contact 20a1, the first strip-like contact 20A and the second auxiliary contact 20a2 may be arranged aligned with each other (as shown in FIGS. 8C, 8D, 8E and 8F), arranged in a stepped arrangement (as shown in FIG. 8A), or arranged in a valley-like arrangement (as shown in FIG. 8B).

To sum up, in the embodiment of the present disclosure, the contacts connecting to the resistance layer (e.g., conductive layer) are designed to have a strip-like shape, and such contacts are referred to as “strip-like contacts” through the specification. Besides, auxiliary contacts are disposed at two sides of the strip-like contacts. Designing such stripe-like contacts can reduce the contact sheet resistance between the contacts and the resistance layer (e.g., conductive layer). Disposing the auxiliary contacts at two sides of the strip-like contacts can control the shapes and dimensions of the strip-like contacts, improve the uniformity, reduce the contact sheet resistance between the contacts and the resistance layer (e.g., conductive layer), and therefore reduce the impact of contact variation on the total resistance of the resistor.

What is claimed is:

1. A semiconductor device, comprising:
a first dielectric layer;
a conductive layer, disposed on the first dielectric layer;
a stop layer, disposed on the conductive layer;
a second dielectric layer, disposed on the stop layer;
a first strip-like contact and a second strip-like contact, separated from each other by a non-zero distance, extending through the second dielectric layer and the stop layer, and electrically connected to the conductive layer;
a first auxiliary contact and a second auxiliary contact, sandwiching the first strip-like contact therebetween, extending through the second dielectric layer, and electrically connected to the conductive layer; and
a third auxiliary contact and a fourth auxiliary contact, sandwiching the second strip-like contact therebetween, extending through the second dielectric layer and electrically connected to the conductive layer,
wherein the first strip-like contact, the second strip-like contact, the conductive layer disposed between the first strip-like contact and the second strip-like contact, the first auxiliary contact, the second auxiliary contact, the third auxiliary contact and the fourth auxiliary contact together form a resistor.

2. The semiconductor device according to claim 1, wherein the stop layer comprises a nitride dielectric material, the conductive layer comprises a metal, an alloy, a metal nitride material or a combination thereof.

3. The semiconductor device according to claim 1, wherein the stop layer comprises silicon nitride, and the conductive layer comprises TIN, SiCr, SiCCr, TaN, NiCr, AlNiCr, TiNiCr or a combination thereof.

4. The semiconductor device according to claim 1, wherein each of the first auxiliary contact, the second auxiliary contact, the third auxiliary contact and the fourth auxiliary contact has a strip-like shape, a square shape, a circular shape or a combination thereof.

5. The semiconductor device according to claim 1, wherein the first strip-like contact, the first auxiliary contact, and the second auxiliary contact have the same shape, dimension or a combination thereof.

6. The semiconductor device according to claim 1, wherein the second strip-like contact, the third auxiliary contact and the fourth auxiliary contact have the same shape, dimension or a combination thereof.

7. The semiconductor device according to claim 1, wherein the second strip-like contact, the first auxiliary contact and the second auxiliary contact have different shapes, dimensions or combinations thereof.

8. The semiconductor device according to claim 1, wherein the second strip-like contact, the third auxiliary contact and the fourth auxiliary contact have different shapes, dimensions or combinations thereof.

9. The semiconductor device according to claim 1, wherein the first strip-like contact, the first auxiliary contact, the second auxiliary contact, the second strip-like contact, the third auxiliary contact and the fourth auxiliary contact are landed on the conductive layer.

10. The semiconductor device according to claim 9, further comprising a transistor disposed right below the conductive layer.

11. The semiconductor device according to claim 1, wherein the first strip-like contact, the first auxiliary contact, the second auxiliary contact, the second strip-like contact, the third auxiliary contact and the fourth auxiliary contact extend through a bottom surface of the conductive layer.

12. The semiconductor device according to claim 11, wherein no transistor is provided right below the conductive layer.

13. The semiconductor device according to claim 1, wherein the first auxiliary contact, the second auxiliary contact, the third auxiliary contact and the fourth auxiliary contact have strip-like shapes, respectively.

14. The semiconductor device according to claim 1, wherein length extension directions of the first auxiliary contact, the second auxiliary contact, the third auxiliary contact and the fourth auxiliary contact are the same as a length extension direction of the conductive layer.

15. The semiconductor device according to claim 1, wherein length extension directions of the first auxiliary contact, the second auxiliary contact, the third auxiliary contact and the fourth auxiliary contact are different from a length extension direction of the conductive layer.

16. The semiconductor device according to claim 1, wherein the first auxiliary contact, the second auxiliary contact, the third auxiliary contact or the fourth auxiliary contact comprise a group of sub-contacts.

17. A semiconductor device, comprising:
a first dielectric layer;
a resistance layer, disposed on the first dielectric layer;
a stop layer, disposed on the resistance layer;
a second dielectric layer, disposed on the stop layer; and
a first group of grid-like contacts and a second group of grid-like contacts, separated by a non-zero distance, extending through the second dielectric layer and the stop layer, and electrically connected to the resistance layer,
wherein the first group of grid-like contacts, the second group of grid-like contacts, and the resistance layer disposed between the first group of grid-like contacts and the second group of grid-like contacts together form a resistor.

18. The semiconductor device according to claim 17, wherein length extension directions of the first group of grid-like contacts and the second group of grid-like contacts are the same as a length extension direction of the resistance layer.

19. The semiconductor device according to claim 17, wherein length extension directions of the first group of grid-like contacts and the second group of grid-like contacts are different from a length extension direction of the resistance layer.

20. The semiconductor device according to claim 17, further comprising:
a plurality of dummy resistance layers, disposed at two sides of the resistance layer.
